(19) United States
(12) Patent Application Publication
(10) Pub. No.: US 2007/0166870 A1
(43) Pub. Date: Jul. 19, 2007

(54) METHOD OF FORMING A PHASE-CHANGEABLE STRUCTURE

(75) Inventors: Young-Soo LIM, Chungcheongbuk-do (KR); Jae-Seung HWANG, Gyeonggi-do (KR); Hyun-Chul KIM, Seoul (KR); Jun-Soo BAE, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/623,890

(22) Filed: Jan. 17, 2007

(30) Foreign Application Priority Data
Jan. 17, 2006 (KR) 2006-04801
Jun. 9, 2006 (KR) 2006-51782

(51) Int. Cl. H01L 21/00

(52) U.S. Cl. 438/95

(57) ABSTRACT

In one embodiment, a phase-changeable structure can be formed by forming a phase-changeable layer on the lower electrode, forming a conductive layer on the phase-changeable layer, etching the conductive layer using a first etching material to form an upper electrode and etching the phase-changeable layer using a second etching material to form a phase-changeable pattern. The first etching material can include a first component containing fluorine. The second etching material does not contain chlorine.

### CROSS-REFERENCE TO RELATED APPLICATION

This application claims benefit of foreign priority to Korean Patent Application No. 10-2006-0004801, filed on Jan. 17, 2006, and Korean Patent Application No. 10-2006-0051782 filed on Jun. 9, 2006, the disclosures of which are incorporated herein by reference in their entireties.

### BACKGROUND

1. Field of Invention

Embodiments of the present invention generally relate to methods of forming phase-changeable structures. More particularly, embodiments of the present invention relate to a method of forming a phase-changeable structure having a switching function.

2. Description of the Related Art

A phase-changeable structure typically includes a lower electrode, an upper electrode and a phase-changeable pattern between the lower electrode and the upper electrode. The phase-changeable pattern includes chalcogenide.

If a predetermined amount of current, generated by a difference in voltage between the lower electrode and the upper electrode, is applied to the phase-changeable pattern, then the phase of the phase-changeable pattern changes from a single crystalline state to an amorphous state. The single crystalline state has a relatively low electric resistance while the amorphous state has a relatively high electric resistance. In addition, if the current applied to the phase-changeable pattern is reduced or removed, the phase of the phase-changeable pattern may revert from the amorphous state back into the single crystalline state.

Because the phase of the phase-changeable pattern is changeable, phase-changeable structures including the lower electrode, the phase-changeable pattern and the upper electrode can be used to generate a switching function.

Generally, the upper electrode is formed of an electrically conductive metal nitride layer. The upper electrode is formed by subjecting the metal nitride layer to a first etching process. In addition, the phase-changeable pattern is formed by subjecting the phase-changeable layer to a second etching process.

Conventionally, etching materials used in the first etching process can generate a large number of defects at an upper-face portion of the phase-changeable pattern where the phase-changeable pattern contacts the upper electrode. In addition, conventional etching materials used in the second etching process can generate a large number of defects at a side-face portion of the phase-changeable pattern.

For example, a conventional method of manufacturing a phase-changeable memory device is understood to be disclosed in Korean Patent Laid-Open Publication No. 2005-053255. In the above conventional method, a lower electrode layer, a phase-changeable layer, an upper electrode layer and an insulating layer are successively formed. Next, the insulating layer, upper electrode layer, phase-changeable layer and the lower electrode layer are successively etched using an etching material including tetraflouromethane, chlorine and argon to form a lower electrode, a phase-changeable pattern, an upper electrode, an insulating pattern. However, an undesirably large number of defects are generated at the phase-changeable pattern formed by the conventional method.

FIG. 1 is a scanning electron microscope (SEM) picture illustrating defects present at a phase-changeable pattern included within a conventional phase-changeable structure.

Referring to FIG. 1, a relatively large number of defects are present at an upper-face portion and at a side-face portion of the phase-changeable pattern (GST). As shown, the upper-face portion electrically contacts an upper electrode. Due to the presence of the defects at the upper- and side-face portions of the phase-changeable pattern, the effective size of the upper- and side-face portions of the phase-changeable pattern are undesirably decreased.

### SUMMARY

Embodiments of the present invention are generally adapted to provide a phase-changeable structure having a phase-changeable pattern with the reduced number of defects.

One exemplary embodiment can be characterized as a method of forming a phase-changeable structure. In such a method, a substrate having a lower electrode formed thereon is provided. Next, a phase-changeable layer is formed on the lower electrode and a conductive layer is formed on the phase-changeable layer. Subsequently, the conductive layer is etched using a first etching material to form an upper electrode and the phase-changeable layer is etched using a second etching material to form a phase-changeable pattern between the upper electrode and the lower electrode. In one embodiment, an atomic percentage of antimony within the phase-changeable layer and an atomic percentage of antimony within the phase-changeable pattern are substantially the same.

Another exemplary embodiment can be characterized as a method of forming a phase-changeable structure in which a substrate having a lower electrode formed thereon is provided, a phase-changeable layer is formed on the lower electrode, an upper electrode is formed on the phase-changeable layer, and the phase-changeable layer is etched using an etching material to form a phase-changeable pattern between the upper and lower electrodes. In such an embodiment, atomic percentages of elements within the phase-changeable layer are substantially the same as atomic percentages of elements within the phase-changeable pattern.

Still another exemplary embodiment can be characterized as a method of forming a phase-changeable structure in which a substrate having a lower electrode formed thereon is provided, a phase-changeable layer is formed on the lower electrode, an upper electrode is formed on the phase-changeable layer, and the phase-changeable layer is etched using an etching material consisting essentially of tetraflouromethane and argon.

### BRIEF DESCRIPTION OF THE DRAWINGS

The above and other advantages of the present invention will become readily apparent by reference to the following detailed description when considered in conjunction with the accompanying drawings in which:

FIG. 1 is a scanning electron microscope (SEM) picture illustrating defects present at a phase-changeable pattern included within a conventional phase-changeable structure;

FIGS. 2 to 4 are cross-sectional views illustrating some embodiments of methods of forming a phase-changeable structure;

FIG. 5 is a scanning electron microscope (SEM) picture of the phase-changeable structure formed according to an exemplary experimental method;

FIG. 6 is a graph illustrating electrical resistance of the phase-changeable pattern shown in FIG. 5 in the presence of an applied current;

FIG. 7 is a scanning electron microscope (SEM) picture of a phase-changeable structure formed according to another exemplary experimental method;

FIG. 8 is a graph illustrating electric resistance of the phase-changeable pattern shown in FIG. 7 in the presence of an applied current; and

FIGS. 9 and 10 are SEM pictures of a silicon oxide layer before and after being subjected to a surface treatment according to yet another exemplary method.

### DETAILED DESCRIPTION OF THE EMBODIMENTS

Exemplary embodiments of the present invention will be described with reference to the accompanying drawings. The embodiments exemplarily described herein may, however, be realized in many different forms and should not be construed as limited to the embodiments set forth herein. Rather, the embodiments are exemplarily provided so that this disclosure will be thorough and complete, and will fully convey the scope of the present invention to those skilled in the art. The principles and features described herein may be employed in varied and numerous embodiments without departing from the scope of the present invention. In the drawings, the size and relative sizes of layers and regions may be exaggerated for clarity. The drawings are not to scale. Like reference numerals designate like elements throughout the drawings.

It will also be understood that when an element or layer is referred to as being “on,” “connected to” and/or “coupled to” another element or layer, the element or layer may be directly on, connected and/or coupled to the other element or layer or intervening elements or layers may be present. In contrast, when an element is referred to as being “directly on,” “directly connected to” and/or “directly coupled to” another element or layer, no intervening elements or layers are present. As used herein, the term “and/or” may include any and all combinations of one or more of the associated listed items.

It will also be understood that, although the terms first, second, etc. may be used herein to describe various elements, components, regions, layers and/or sections. These elements, components, regions, layers and/or sections should not be limited by these terms. These terms may be used to distinguish one element, component, region, layer and/or section from another element, component, region, layer and/or section. For example, a first element, component, region, layer and/or section discussed below could be termed a second element, component, region, layer and/or section without departing from the teachings of the present invention.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (rotated 90 degrees or at other orientations) and the spatially relative descriptors used herein interpreted accordingly.

The terminology used herein is for the purpose of describing particular embodiments only and is not intended to limit of the invention. As used herein, the singular terms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof.

Unless otherwise defined, all terms (including technical and scientific terms) used herein may have the same meaning as what is commonly understood by one of ordinary skill in the art. It will be further understood that terms, such as those defined in commonly used dictionaries, should be interpreted as having a meaning that is consistent with their meaning in the context of this specification and the relevant art and will not be interpreted in an idealized and/or overly formal sense unless expressly so defined herein.

Embodiments are exemplarily described with reference to cross-sectional illustrations that are idealized schematic illustrations. As such, variations from the shapes of the illustrations as a result, for example, of manufacturing techniques and/or tolerances, are to be expected. Accordingly, embodiments described herein should not be construed as being limited to the particular shapes of regions illustrated herein but are to include deviations in shapes that result, for example, from manufacturing. For example, a region illustrated as a rectangle will, typically, have rounded or curved features. Accordingly, the regions illustrated in the figures are schematic in nature of a device and are not intended to limit the scope of the present invention.

### Embodiment 1

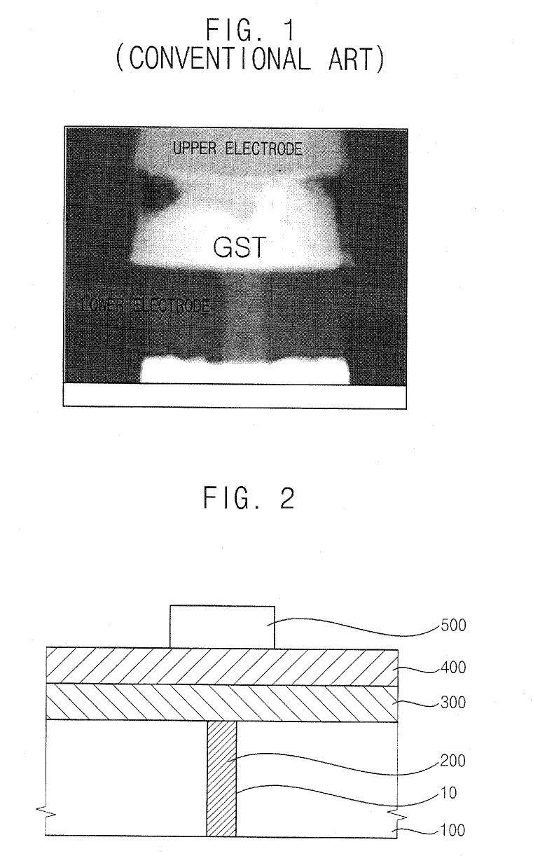

FIGS. 2 to 4 are cross-sectional views illustrating a method of forming a phase-changeable structure in accordance with a first embodiment of the present invention.

Referring to FIG. 2, an insulating layer 100 having a hole 10 defined therein is formed. The insulating layer 100 may include a material such as an oxide or a nitride. For example, the insulating layer 100 may include a material such as phosphor silicate glass (PSG), BPSG boro-phosphor silicate glass (BPSG), undoped silicate glass (USG), spin on glass (SOG), tetra ethyl ortho silicate (TEOS), plasma enhanced-TEOS (PE-TEOS), flowable oxide (FOX), high density plasma-chemical vapor deposition oxide (HDP-CVD), silicon nitride, or the like, or combinations thereof.

A lower electrode 200 is formed within the hole 10. The lower electrode 200 may include a material such as a metal, a metal nitride, or the like or combinations thereof. For example, the lower electrode 200 may include a material such as tungsten, titanium, titanium nitride, tantalum, tantalum nitride, molybdenum nitride, niobium nitride, titanium silicon nitride, aluminum, titanium aluminum nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride, tantalum aluminum nitride or combinations thereof. In another embodiment, the lower electrode 200 may include a material such as polysilicon doped with impurities. In the illustrated embodiment, an upper surface of the insulating layer 100 may be substantially coplanar with an upper surface of the lower electrode 200.

A phase-changeable layer 300 is formed on the insulating layer 100 and on the lower electrode 200. The phase-changeable layer 300 may include a material such as a chalcogenide.

The chalcogenide may, for example, include germanium (Ge), antimony (Sb) and tellurium (Te), or the like.

A conductive layer 400 is formed on the phase-changeable layer 300. The conductive layer 400 may include a material such as a metal, metal nitride or combinations thereof. For example, the conductive layer 400 may include a material such as tungsten, titanium, titanium nitride, tantalum, tantalum nitride, molybdenum nitride, niobium nitride, titanium silicon nitride, aluminum, titanium aluminum nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride, tantalum aluminum nitride or combinations thereof.

The conductive layer 400 may be formed according to any suitable process such as a sputtering process, a chemical vapor deposition (CVD) process, an electron beam deposition process, an atomic layer deposition (ALD) process, a pulse laser deposition (PLD) process or the like.

A mask pattern 500 is formed on the conductive layer 400. The mask pattern 500 may include a material having an etch selectivity with respect to the conductive layer 400 and the phase-changeable layer 300.

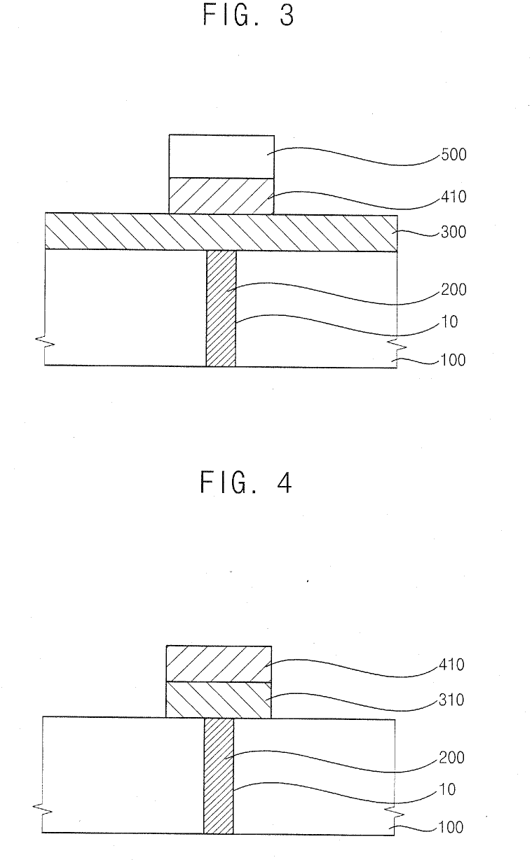

Referring to FIG. 3, a first etching process is performed on the conductive layer 400 using the mask pattern 500 as an etch mask. As a result of the first etching process, an upper electrode 410 is formed. The first etching process may be accomplished using a first etching material including a first component containing fluorine (F). For example, the first component may be tetraflouromethane (CF₄), trifluoromethane (CHF₃), difluoromethane (CH₂F₂), monofluoromethane (CH₃F), or the like or combinations thereof.

Although not illustrated in FIG. 3, a portion of the phase-changeable layer 300 may be partially removed during the first etching process because the first etching material etches the phase-changeable layer 300 at a substantially larger etch rate it etches the conductive layer 400.

Fluorine has a relatively large chemical activity because the fluorine is an element of a halogen group. Accordingly, when the upper electrode is formed according to the aforementioned first etching process, a fluorine compound may remain on surfaces of the phase-changeable layer 300, the upper electrode 410 and the mask pattern 500. For example, if the mask pattern includes silicon oxide, the fluorine compound remaining on the mask pattern 500 may include a silicon fluoride. Moreover, if the conductive layer 400 includes titanium, the fluorine compound remaining on the upper electrode 410 may include a titanium fluoride.

The fluorine compounds may be removed by performing a first surface treatment on the phase-changeable layer 300, the upper electrode 410 and the mask pattern 500. The first surface treatment may be performed using an inert gas. The inert gas may include helium (He), neon (Ne), argon (Ar), krypton (Kr), Xenon (Xe) or radon (Rn). These may be used alone or in combinations thereof.

The first surface treatment is performed in a chamber having a source electrode and a bias electrode. The bias electrode is combined with a chuck located at a lower portion of the chamber. The source electrode is located over the chamber. The inert gas may be excited into a plasma state according to a difference in voltage between the source electrode and the bias electrode.

If the first surface treatment is performed for less than about 10 seconds, the fluorine compounds may not be sufficiently removed. On the other hand, if the first surface treatment is performed for more than about 120 seconds, the phase-changeable layer 300, the upper electrode 410 and the mask pattern 500 may be undesirably damaged. Accordingly, the first surface treatment may be performed for a time ranging between about 10 seconds and about 120 seconds.

It will be appreciated that the first surface treatment performed on the phase-changeable layer 300, the upper electrode 410 and the mask pattern 500 is an optional process. Accordingly, the first surface treatment may not be performed.

Referring to FIG. 4, a second etching process is performed on the phase-changeable layer 300. The second etching process may be accomplished using a second etching material that does not contain chlorine. As a result of the second etching process, a phase-changeable pattern 310a is formed between the upper electrode 410 and the lower electrode 200.

If the second etching material includes chlorine, the chlorine may chemically react with the phase-changeable layer 300, thereby generating defects, particularly at a side-face portion of the phase-changeable pattern 310. As described above, the effective size of the side-face portion may decrease due to the presence of defects. If the phase-changeable layer 300 includes germanium, antimony and tellurium, chlorine present within the second etching material can chemically react with an excessive amount of antimony. As a result, the atomic percentage of antimony is undesirably decreased within the resultant phase-changeable pattern 310. Accordingly, it is desirable for the second etching material not to include chlorine.

The second etching process is performed in a chamber having a source electrode and a bias electrode. The bias electrode is combined with a chuck located at a lower portion of the chamber. The source electrode is located over the chamber. The second etching material may be excited into a plasma state according to a difference in voltage between the source electrode and the bias electrode.

In one embodiment, the second etching material may include a material such as helium (He), neon (Ne), argon (Ar), krypton (Kr), xenon (Xe) radon (Rn), or combinations thereof. In this case, the second etching material may have a plasma state.

In another embodiment, the second etching material may further include fluorine. Fluorine may be provided in the form of a material such as tetraflouromethane, trifluoromethane, difluoromethane, monofluoromethane or combinations thereof.

Fluorine has a relatively large a chemical activity because the fluorine is an element of a halogen group. Accordingly, if the phase-changeable pattern 310 is formed by the second etching process using the second etching material described above, a fluorine compound may remain on surfaces of the insulating layer 100, the phase-changeable pattern 310, the upper electrode 410 and the mask pattern 500.

For example, if the mask pattern includes silicon oxide, the fluorine compound remaining on the mask pattern 500 may include a silicon fluoride. Moreover, if the upper electrode 410 includes titanium, the fluorine compound remaining on the upper electrode 410 may include a titanium fluoride.

The fluorine compounds may be removed by performing a second surface treatment on the insulating layer 100, the phase-changeable pattern 310, the upper electrode 410 and the mask pattern 500. The second surface treatment may be performed using an inert gas. The inert gas may include helium (He), neon (Ne), argon (Ar), krypton (Kr), Xenon (Xe) or radon (Rn). These may be used alone or in combinations thereof.

The second surface treatment is performed in a chamber having a source electrode and a bias electrode. The bias electrode is combined with a chuck located at a lower portion of the chamber. The source electrode is located over the chamber. The inert gas may be excited into a plasma state according to a difference in voltage between the source electrode and the bias electrode. In one embodiment, the second surface treatment may be performed in the same chamber where the second etching process was performed.

If the second surface treatment is performed for less than about 10 seconds, the fluorine compounds may not be sufficiently removed. On the other hand, if the second surface treatment is performed for more than about 120 seconds, the insulating layer 100, the phase-changeable pattern 310, the upper electrode 410 and the mask pattern 500 may be undesirably damaged. Accordingly, the second surface treatment may be performed for a time ranging between about 10 seconds and about 120 seconds.

It will be appreciated that the second surface treatment performed on the insulating layer 100, the phase-changeable pattern 310, the upper electrode 410 and the mask pattern 500 is an optional process. Accordingly, the second surface treatment may not be performed.

After the phase-changeable pattern 310 has been formed (or after the optional second surface treatment has been performed), the mask pattern 500 may be removed from the surface of the upper electrode 410 to yield the structure shown in FIG. 4.

### Embodiment 2

A method of forming a phase-changeable structure in accordance with a second embodiment is similar to the method described above in the first embodiment except that the first etching material further includes a second component. Accordingly, redundant explanation will be omitted for the sake of brevity.

In one embodiment, the second component may include a material such as helium, neon, argon, krypton, xenon, radon, or combinations thereof. The first etching material may have a plasma state.

A first etching process is performed in a chamber having a source electrode and a bias electrode. The bias electrode is installed at a chuck located at a lower portion of the chamber. The chuck may support the aforementioned conductive layer 400 which is to be subjected to the first etching process. The source electrode is located at an upper portion of the chamber. Here, the source electrode and the bias electrode are utilized to change a stage of the first etching material into a plasma state.

In one embodiment, a first electric power and a second electric power are applied to the source electrode and the bias electrode, respectively. If a ratio of the first electric power to the second electric power is less than about 2.5:1, then the first etching process is relatively inefficient at etching the conductive layer 400. On the other hand, if the ratio of the first electric power to the second electric power is greater than about 10:1, then it can be difficult to control the first etching process effectively. Accordingly, the ratio of the first electric power to the second electric power may be in a range between about 2.5:1 and about 10:1. In one exemplary embodiment, the ratio of the first electric power to the second electric power may be about 5:1. Accordingly, the first electric power and the second electric power may be selected to be about 1,000 Watt and about 200 Watt, respectively.

If a pressure of the chamber is less than about 1 mTorr, then the first etching process is relatively inefficient at etching the conductive layer 400. On the other hand, if the pressure of the chamber is more than about 10 mTorr, then it can be difficult to control the first etching process effectively. Accordingly, the pressure of the chamber may be in a range between about 1 mTorr and about 10 mTorr. In one exemplary embodiment, the pressure of the chamber may be about 5 mTorr.

If a flow ratio of the first component to the second component is less than about 1:4, then a byproduct such as metal fluoride may be generated. On the other hand, if the flow ratio of the first component to the second component is greater than about 3:2, then the efficiency of the first etching process decreases. Accordingly, the flow ratio of the first component to the second component may be in a range between about 1:4 and about 3:2. In one exemplary embodiment, the flow ratio of the first component to the second component may be about 2:3.

### Embodiment 3

A method of forming a phase-changeable structure in accordance with a third embodiment is similar to the method described above in the second embodiment except that the first etching material further includes a third component. Accordingly, redundant explanation will be omitted for the sake of brevity.

In one embodiment, the third component may include chlorine. If the third component is included as a component of the first etching material, then the conductive layer 400 may be etched at a relatively low temperature.

The aforementioned second component in the first etching material may prevent chlorine from chemically reacting with the phase-changeable layer 300. In addition, the second component in the first etching material may prevent chlorine from infiltrating into an interface between the phase-changeable layer 300 and an upper electrode 410. Accordingly, the second component in the first etching material may help to reduce the number of defects generated at an upper-face portion of the phase-changeable layer 300 (i.e., where the phase-changeable layer 300 contacts the upper electrode 410).

### FIRST EXPERIMENTAL EXAMPLE

### Etching a Titanium Nitride Layer

A chamber was prepared. A chuck existed at a lower portion of the chamber. A bias electrode was installed at the chuck. A source electrode existed at an upper portion of the chamber. A titanium nitride layer was then disposed on the chuck. A pressure of the chamber was about 5 mTorr. A first etching material including the aforementioned first component and second component was introduced into the chamber. The first component was tetraflouromethane and the second component was argon. A flow ratio of the first component to the second component was about 2:3.

A first electric power and a second electric power were applied to the source electrode and the bias electrode, respectively, at a ratio of about 5:1. Particularly, the first electric power and the second electric power were about 1,000 Watt and about 200 Watt, respectively, and the first etching material existed in a plasma state due to the first and second electric powers.

The titanium nitride layer was etched under above-described conditions at an etch rate of about 11.4 Å/sec. It was found that this etch rate was satisfactory and an etch byproduct such as titanium fluoride was not generated.

### SECOND EXPERIMENTAL EXAMPLE

### Etching a Phase-Changeable Layer without Chlorine

An insulating layer having a hole was formed. The insulating layer included silicon nitride. A lower electrode was then formed in the hole. The lower electrode included titanium nitride. An upper surface of the insulating layer was substantially coplanar with an upper surface of the lower electrode.

A phase-changeable layer was formed on the insulating layer and on the lower electrode. The phase-changeable layer included germanium, antimony and tellurium in atomic percentages of about 24.8%, about 24.5% and about 50.6%, respectively.

A titanium nitride layer was formed on the phase-changeable layer. A first etching process was performed on the titanium nitride layer to form an upper electrode. The first etching process was performed using a first etching material including the aforementioned first component, second component and third component. The first component, second component and third component were tetraflouromethane, argon and chlorine, respectively. The first etching material existed in a plasma state.

After the first etching process, a second etching process was performed on the phase-changeable layer to form a phase-changeable pattern. The second etching material included tetraflouromethane and argon and existed in a plasma state. That is, the second etching material consisted essentially of tetraflouromethane and argon. As a result of the second etching process, a phase-changeable pattern was formed between the lower electrode and the upper electrode so as to form a phase-changeable structure including the lower electrode, the phase-changeable pattern and the upper electrode.

Atomic percentages of germanium, antimony and tellurium in the phase-changeable pattern were determined to be about 20%, about 24.7% and about 55%, respectively. Accordingly, the atomic percentages of germanium, antimony and tellurium included in the phase-changeable pattern were determined to be substantially the same as the atomic percentages of germanium, antimony and tellurium included in the phase-changeable layer.

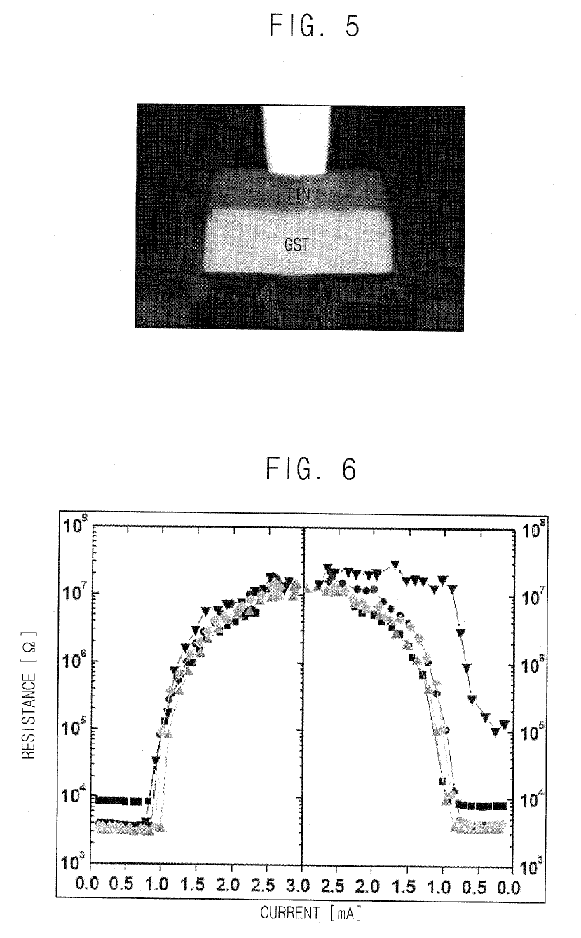

FIG. 5 is a scanning electron microscope (SEM) picture of the phase-changeable structure formed according to the second experimental example.

Referring to FIG. 5, a relatively small number of defects exist at an upper-face portion of the phase-changeable pattern where the phase-changeable pattern electrically contacts the upper electrode. In addition, a relatively small number of defects exist at a side-face portion of the phase-changeable pattern because there was no difference in composition between the phase-changeable layer and the phase-changeable pattern.

FIG. 6 is a graph illustrating electrical resistance of the phase-changeable pattern formed according to the second experimental example in the presence of an applied current.

Referring to FIG. 6, when the current provided to the phase-changeable pattern is less than about 1.0 mA, a phase of the phase-changeable pattern exhibits a single crystalline state having a relatively low electric resistance. On the other hand, when the current provided to the phase-changeable pattern is greater than about 1.5 mA, the phase of the phase-changeable pattern exhibits an amorphous state having a relatively high electric resistance. Accordingly, a phase-changeable structure including the phase-changeable pattern formed as exemplarily described with respect to the second experimental example has a desirable switching function.

### THIRD EXPERIMENTAL EXAMPLE

### Etching a Phase-Changeable Layer with Chlorine

An insulating layer having a hole was formed. The insulating layer included silicon nitride. A lower electrode was then formed in the hole. The lower electrode included titanium nitride. An upper surface of the insulating layer was substantially coplanar with an upper surface of the lower electrode.

A phase-changeable layer was formed on the insulating layer and on the lower electrode. The phase-changeable layer included germanium, antimony and tellurium in atomic percentages of about 24.8%, about 24.5% and about 50.6%, respectively.

A titanium nitride layer was formed on the phase-changeable layer. The titanium nitride layer and the phase-changeable layer were successively etched to form an upper electrode and a phase-changeable pattern, respectively. Specifically, both the titanium nitride layer and the phase-changeable layer were etched in etching processes containing chlorine.

Atomic percentages of germanium, antimony and tellurium included in the phase-changeable pattern were determined to be about 22.5%, about 3.8% and about 73.7%, respectively. Accordingly, the atomic percentages of germanium, antimony and tellurium included in the phase-changeable pattern were determined to be substantially different from the atomic percentages of germanium, antimony and tellurium included in phase-changeable layer.

Particularly, the atomic percentage of antimony included in the phase-changeable layer was about 24.5% while the atomic percentage of antimony included in the phase-changeable pattern was about 3.8%. Accordingly, the atomic percentage of antimony decreased during etching of the titanium nitride and phase-changeable layers.

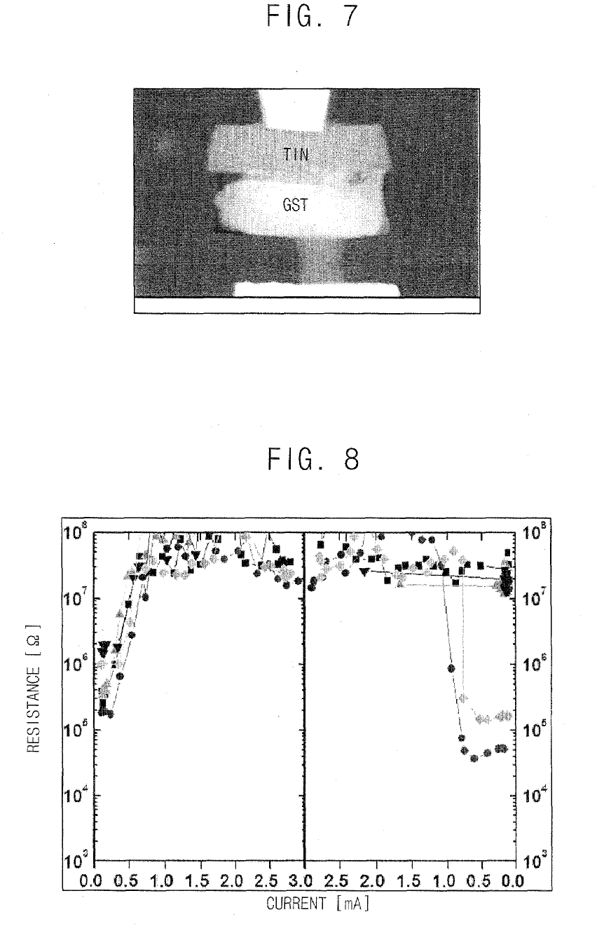

FIG. 7 is a scanning electron microscope (SEM) picture of the phase-changeable structure formed according to the third experimental example.

Referring to FIG. 7, a relatively large number of defects exist at an upper-face portion of the phase-changeable pattern where the phase-changeable pattern electrically contacts the upper electrode. In addition, a relatively large number of defects exist at a side-face portion of the phase-changeable pattern because there was a difference in composition between the phase-changeable layer and the phase-changeable pattern.

FIG. 8 is a graph illustrating electric resistance of the phase-changeable pattern formed according to the third experimental example in the presence of an applied current.

Referring to FIG. 8, a phase of the phase-changeable pattern exhibits an amorphous state having a relatively large electric resistance even when a current is not provided to the phase-changeable pattern. Accordingly, the phase-changeable pattern formed according to the third experimental example does not have a desirable switching function.

### FOURTH EXPERIMENTAL EXAMPLE

### Removing a Fluorine Compound

A silicon oxide layer was formed on a semiconductor substrate. Thereafter, tetraflouromethane was provided to the silicon oxide layer to form a silicon fluorine compound on a surface thereof.

Thereafter, a surface treatment was performed on the silicon oxide layer in a chamber having a source electrode and a bias electrode. Particularly, a power of 1,000 Watt and 0 W were applied to the source electrode and the bias electrode, respectively. An argon gas was also provided into the chamber.

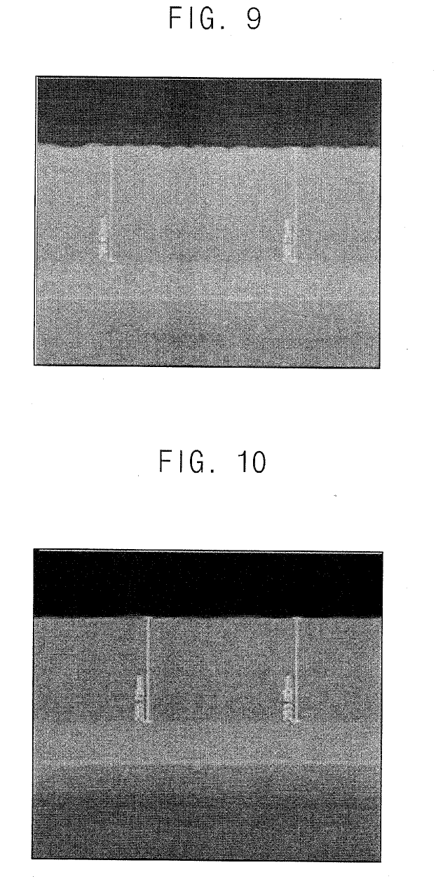

FIG. 9 is an SEM picture of the silicon oxide layer before the surface treatment according to the fourth experimental example was performed.

Referring to FIG. 9, the surface of the silicon oxide layer is substantially uneven because the silicon fluorine compound is on the surface of the silicon oxide layer.

FIG. 10 is an SEM picture of the silicon oxide layer after the surface treatment according to the fourth experimental example was performed for thirty seconds.

Referring to FIG. 10, the surface of the silicon oxide layer is substantially even because the silicon fluorine compound remaining on the surface of the silicon oxide layer was removed. A removal rate of the silicon fluorine compound was determined to be about 300 Å/min.

According to the exemplary embodiments described above, a phase-changeable pattern located between the lower electrode and the upper electrode can be formed to have a relatively small number of defects at upper- and side-face portions thereof. As described above, a phase-changeable structure can be formed according to a process where a lower electrode is initially formed, a phase-changeable layer including chalcogenide is then formed on the lower electrode, a conductive layer including metal is formed on the phase-changeable layer, the conductive layer is then etched using a first material including a first component having fluorine to form an upper electrode, and the phase-changeable layer is etched using a second material that does not include chlorine to form a phase-changeable pattern between the upper electrode and the lower electrode.

The chalcogenide may include germanium, antimony and tellurium. The conductive layer may include tungsten, titanium, titanium nitride, tantalum, tantalum nitride, molybdenum nitride, niobium nitride, titanium silicon nitride, aluminum, titanium aluminum nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride, tantalum aluminum nitride or combinations thereof.

The first component may be tetraflouromethane, trifluoromethane, difluoromethane, monofluoromethane or combinations thereof. The second etching material may include helium, neon, argon, krypton, xenon, radon or combinations thereof. The second etching material may have a plasma state. The second etching material may further include fluorine. The fluorine may be provided from tetraflouromethane, trifluoromethane, difluoromethane, monofluoromethane or combinations thereof.

A fluorine compound remaining on the upper electrode and the phase-changeable layer may be removed after the upper electrode is formed and before the phase-changeable pattern is formed. The fluorine compound is removed using a material including helium, neon, argon, krypton, xenon, radon or combinations thereof. The material may have a plasma state. The fluorine compound may be removed for about 10 seconds to about 120 seconds.

A fluorine compound remaining on the insulating layer, the upper electrode, the upper electrode and the phase-changeable pattern may be removed after the phase-changeable pattern is formed. The fluorine compound is removed using a material including helium, neon, argon, krypton, xenon, radon or combinations thereof. The material may have a plasma state. The fluorine compound may be removed for about 10 seconds to about 120 seconds.

In accordance with an embodiment of the present invention, a lower electrode is initially formed. A phase-changeable layer including chalcogenide is formed on the lower electrode. A conductive layer including metal is formed on the phase-changeable layer. The conductive layer is etched using a first etching material including a first component and a second component to form an upper electrode. The first component includes fluorine. The phase-changeable layer is etched using a second etching material that does not include chlorine to form a phase-changeable pattern between the upper electrode and the lower electrode.

The chalcogenide may include germanium, antimony and tellurium. The conductive layer may include tungsten, titanium, titanium nitride, tantalum, tantalum nitride, molybdenum nitride, niobium nitride, titanium silicon nitride, aluminum, titanium aluminum nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride, tantalum aluminum nitride or combinations thereof.

The first component may be tetraflouromethane, trifluoromethane, difluoromethane, monofluoromethane or combinations thereof. The second component may be helium, neon, argon, krypton, xenon, radon or combinations thereof. The first etching material may have a plasma state. An etching process required for etching the conductive layer to form the upper electrode may be performed in a chamber having a source electrode and a bias electrode. A ratio of a first electric power applied to the bias electrode with respect to a second electric power applied to the source electrode may be about 2.5:1 to about 10:1. A pressure of the chamber may be about 1 mTorr to about 10 mTorr.

A flow rate of the second component with respect to the first component may be about 1:4 to about 3:2. The second etching material may be helium, neon, argon, krypton, xenon, radon or combinations thereof. The second etching material may have a plasma state. The second etching material may further include fluorine. The fluorine may be provided from tetraflouromethane, trifluoromethane, difluoromethane, monofluoromethane or combinations thereof.

A fluorine compound remaining on the upper electrode and the phase-changeable layer may be removed after the upper electrode is formed and before the phase-changeable pattern is formed. The fluorine compound is removed using a material including helium, neon, argon, krypton, xenon, radon or combinations thereof. The material may have a plasma state. The fluorine compound may be removed for about 10 seconds to about 120 seconds.

A fluorine compound remaining on the insulating layer, the upper electrode, the upper electrode and the phase-changeable pattern may be removed after the phase-changeable pattern is formed. The fluorine compound is removed using a material including helium, neon, argon, krypton, xenon, radon or combinations thereof. The material may have a plasma state. The fluorine compound may be removed for about 10 seconds to about 120 seconds.

The foregoing is illustrative of the present invention and is not to be construed as limiting thereof. Although a few embodiments of this invention have been described, those skilled in the art will readily appreciate that many modifications are possible in the embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A method of forming a phase-changeable structure, the method comprising:
providing a substrate having a lower electrode formed thereon;
forming a phase-changeable layer on the lower electrode;
forming a conductive layer including metal on the phase-changeable layer;
etching the conductive layer using a first etching material to form an upper electrode, wherein the first etching material comprises a first component containing fluorine; and
etching the phase-changeable layer using a second etching material to form a phase-changeable pattern between the upper electrode and the lower electrode, wherein the second etching material does not include chlorine.

2. The method of claim 1, wherein the phase-changeable layer comprises a chalcogenide material.

3. The method of claim 2, wherein the phase-changeable layer comprises germanium, antimony and tellurium.

4. The method of claim 1, wherein the conductive layer comprises a metal, metal nitride, or combinations thereof.

5. The method of claim 1, the conductive layer comprises tungsten, titanium, titanium nitride, tantalum, tantalum nitride, molybdenum nitride, niobium nitride, titanium silicon nitride, aluminum, titanium aluminum nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride, tantalum aluminum nitride or combinations thereof.

6. The method of claim 1, wherein the first component comprises tetraflouromethane, trifluoromethane, difluoromethane, monofluoromethane or combinations thereof.

7. The method of claim 1, wherein the first etching material comprises helium, neon, argon, krypton, xenon, radon or combinations thereof

8. The method of claim 7, wherein the first etching material further comprises a second component containing an inert gas, and wherein etching the conductive layer comprises:
inserting the substrate into a chamber, wherein the chamber comprises a source electrode and a bias electrode;
applying a first electric power to the source electrode and a second electric power to the bias electrode, wherein a ratio of the first electric to the second electric power is between about 2.5:1 and about 10:1;
maintaining a pressure within the chamber between about 1 mTorr and about 10 mTorr; and
introducing the first component into the chamber at a first flow rate and introducing the second component into the chamber at a second flow rate, wherein a ratio of the flow rate to the second flow rate is between about 1:4 and about 3:2.

9. The method of claim 1, wherein the first etching material comprises another component containing chlorine.

10. The method of claim 1, wherein etching the conductive layer using the first etching material comprises subjecting the conductive layer to a plasma of the first etching material.

11. The method of claim 1, wherein the second etching material comprises helium, neon, argon, krypton, xenon, radon or combinations thereof.

12. The method of claim 11, wherein the second etching material further comprises fluorine.

13. The method of claim 12, wherein the fluorine is comprised within the second etching material as tetraflouromethane, trifluoromethane, difluoromethane, monofluoromethane or combinations thereof.

14. The method of claim 1, wherein etching the phase-changeable layer using the second etching material comprises subjecting the phase-changeable layer to a plasma of the second etching material.

15. The method of claim 1, further comprising:
generating a fluorine compound on the upper electrode and the phase-changeable layer before etching the phase-changeable layer; and
removing the fluorine compound before etching the phase-changeable layer.

16. The method of claim 15, wherein removing the fluorine compound comprises exposing the fluorine compound to a plasma comprising helium, neon, argon, krypton, xenon, radon or combinations thereof.

17. The method of claim 16, wherein removing the fluorine compound comprises exposing the fluorine compound to the plasma about 10 seconds to about 120 seconds.

18. The method of claim 1, further comprising:
generating a fluorine compound on the phase-changeable pattern and the upper electrode; and
removing the fluorine compound.

19. The method of claim 18, wherein removing the fluorine compound comprises exposing the fluorine compound to a plasma comprising helium, neon, argon, krypton, xenon, radon or combinations thereof.

20. The method of claim 19, wherein removing the fluorine compound comprises exposing the fluorine compound to the plasma about 10 seconds to about 120 seconds.

21. A method of forming a phase-changeable structure, the method comprising:
providing a substrate having a lower electrode formed thereon;
forming a phase-changeable layer on the lower electrode;
forming an upper electrode on the phase-changeable layer; and
etching the phase-changeable layer using an etching material to form a phase-changeable pattern between the upper and lower electrodes, wherein atomic percentages of elements within the phase-changeable layer are substantially the same as atomic percentages of elements within the phase-changeable pattern.

22. The method of claim 21, wherein the etching material comprises helium, neon, argon, krypton, xenon, radon or combinations thereof.

23. The method of claim 22, wherein the etching material further comprises fluorine.

24. The method of claim 23, wherein the fluorine is comprised within the etching material as tetraflouromethane, trifluoromethane, difluoromethane, monofluoromethane or combinations thereof.

25. The method of claim 21, wherein the phase-changeable layer comprises germanium, antimony and tellurium.

26. A method of forming a phase-changeable structure, the method comprising:
providing a substrate having a lower electrode formed thereon;
forming a phase-changeable layer on the lower electrode;
forming an upper electrode on the phase-changeable layer; and
etching the phase-changeable layer using an etching material consisting essentially of tetraflouromethane and argon.
